(19) United States
(12) Patent Application Publication
(10) Pub. No.: US 2026/0013313 A1
(43) Pub. Date: Jan. 8, 2026

(54) Polymeric Back Interface Layer for CdTe/CdSeTe Solar Cells

(71) Applicant: The University of Toledo, Toledo, OH (US)

(72) Inventors: Randall J. Ellingson, Toledo, OH (US); Scott Lambright, Toledo, OH (US); Abasi Abudulimu, Toledo, OH (US); Michael Heben, Toledo, OH (US); Robert Earl Cannon, Toledo, OH (US); Adam Phillips, Toledo, OH (US)

(73) Assignee: The University of Toledo, Toledo, OH (US)

(21) Appl. No.: 19/258,048

(22) Filed: Jul. 2, 2025

Related U.S. Application Data
(60) Provisional application No. 63/666,842, filed on Jul. 2, 2024.

(51) Int. Cl. H10K 30/40; H10K 30/50; H10K 30/81; H10K 30/86; H10K 71/12; H10K 71/40; H10K 71/60; H10K 85/10; H10K 85/30; H10K 85/60; H10K 102/20

(52) U.S. Cl. CPC H10K 30/40; H10K 30/50; H10K 30/81; H10K 30/86; H10K 71/12; H10K 71/40; H10K 71/60; H10K 85/146; H10K 85/331; H10K 85/654; H10K 2102/20

(57) ABSTRACT

Photovoltaic devices, and methods of making the same, are described. The photovoltaic devices includes a hole-transport layer which includes poly(9-vinylcarbazole) (PVK).

### RELATED APPLICATIONS

This application claims priority to U.S. Provisional Application No. 63/666,842 filed under 35 U.S.C. § 111(b) on Jul. 2, 2024, the disclosure of which is incorporated herein by reference in its entirety.

### STATEMENT REGARDING FEDERALLY SPONSORED RESEARCH

This invention was made with government support under Grant Number DE-EE0008974 awarded by the Department of Energy, Grant Number 37989 awarded by the Department of Energy, Grant Number FA9453-21-C-005 awarded by the Air Force Research Lab, and Grant Number FA9453-19-C-100 awarded by the Air Force Research Lab. The government has certain rights in this invention.

### BACKGROUND

The advantages of using cadmium telluride (CdTe)-based PV over conventional silicon PV include a less energy intensive (i.e., cheaper) fabrication, a more eco-friendly manufacturing (lower greenhouse gas emissions), the shortest energy-payback time, and a more stable performance over the lifetime of the module. CdTe thin film photovoltaics (PV) has been the most successful thin film technology to be manufactured on an industrial scale in terms of deployed power capacity. This has been achieved while an ideal back contact suitable for CdTe PV devices that is also highly manufacturable has remained elusive. One conventional back contact is a copper-doped zinc telluride (ZnTe:Cu) hole transport layer (HTL) that, while matched well with CdTe in valence band maximum (VBM) and conduction band minimum (CBM) for the function of an HTL, results in an unpassivated, defect-riddled CdTe/ZnTe interface with high surface recombination velocity (SRV) at the absorber back surface. Therefore, a ZnTe back contact is not ideal, leaving a need for better back contact materials and processes in the CdTe PV industry.

### SUMMARY

Provided is a photovoltaic device comprising a front contact; one or more layers on the front contact including a photovoltaic heterojunction, the photovoltaic heterojunction comprising an absorber layer, wherein the absorber layer comprises cadmium and tellurium; a hole transport layer on the absorber layer, wherein the hole transport layer comprises poly(9-vinylcarbazole) (PVK); and a back contact on the hole transport layer.

In certain embodiments, the absorber layer comprises CdTe. In certain embodiments, the absorber layer comprises CdSeTe.

In certain embodiments, the back contact comprises Au. In certain embodiments, the back contact is not doped with copper. In certain embodiments, the back contact is free of copper.

In certain embodiments, the absorber layer is doped with arsenic. In certain embodiments, the absorber layer is doped with arsenic and not copper. In particular embodiments, the absorber layer comprises CdSeTe. In certain embodiments, the photovoltaic device is entirely free of copper.

In certain embodiments, the absorber layer is in direct contact with the front contact, and the photovoltaic heterojunction is formed between the front contact and the absorber layer.

In certain embodiments, the PVK is doped with 4-tert-butylpyridine (4-TBP), lithium bis(trifluoromethanesulfonyl)imide (Li-TFSI), or cobalt(III) 2,2′,2″-(1,3,5-benzinetriyl)-tris(1-phenyl-1-H-benzimidazole) (FK209-Co).

In certain embodiments, the photovoltaic device further comprises a Cd-rich oxidized interface layer between the absorber layer and the hole transport layer. In particular embodiments, the Cd-rich oxidized interface layer comprises a mixture of CdO and CdTeO.

Further provided is a photovoltaic device comprising a plurality of thin film layers including a photovoltaic heterojunction formed between a first contact layer having n-type conductivity and a second contact layer having p-type conductivity; wherein the plurality of thin film layers includes an absorber layer comprising cadmium and tellurium, wherein the absorber layer forms the photovoltaic heterojunction with one or more other layers of the plurality of thin film layers; and wherein the plurality of thin film layers includes a hole transport layer between the absorber layer and the second contact layer, the hole transport layer comprising poly(9-vinylcarbazole).

In certain embodiments, the absorber layer is doped with arsenic. In certain embodiments, the absorber layer is not doped with copper. In certain embodiments, the absorber layer is doped with arsenic. In particular embodiments, the absorber layer comprises CdSeTe. In certain embodiments, the photovoltaic device is entirely free of copper.

Further provided is a photovoltaic device comprising a first electrically conductive layer having n-type conductivity; an absorber layer comprising cadmium and tellurium on the first electrically conductive layer, the absorber layer forming a photovoltaic heterojunction with either the first electrically conductive layer or an additional layer between the first electrically conductive layer and the absorber layer; and a back contact structure on the absorber layer comprising a hole transport material and a second electrically conductive layer, wherein the hole transport material comprises poly(9-vinylcarbazole) (PVK) and the second electrically conductive layer has p-type conductivity.

Further provided is a photovoltaic device comprising a support; a transparent conductive oxide layer on the support; an absorber layer comprising CdSeTe directly on the transparent conductive oxide layer; a hole transport layer comprising poly(9-vinylcarbazole) (PVK) on the absorber layer; and a back contact layer on the hole transport layer, wherein the hole transport layer is between the absorber layer and the back contact layer. In certain embodiments, the photovoltaic device further comprises a Cd-rich oxidized interface layer directly on the absorber layer and between the absorber layer and the hole transport layer.

Further provided is a method of making a photovoltaic device, the method comprising exposing a layer stack having an absorber layer material comprising cadmium and tellurium deposited on a surface thereof to a bath comprising KOH; thermally annealing the layer stack at a first elevated temperature for a first period of time; depositing poly(9-vinylcarbazole) (PVK) from a solution onto the surface; and thermally annealing the layer stack at a second elevated temperature for a second period of time, wherein the second elevated temperature is 150° C. or less. In certain embodiments, the method further comprises doping the PVK layer with 4-TBP, Li-TFSI, and/or FK209-Co. In certain embodiments, the method further comprises depositing a back contact on the PVK.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIGS. 1A-1B: Schematics of non-limiting example photovoltaic devices in accordance with the present disclosure.

FIG. 2: Transmission spectrum of representative PVK-HTL film on borosilicate glass, with glass-only control. The inset shows the chemical structure of PVK.

FIG. 3: Schematic of device thin film stack tested in the examples herein.

FIGS. 4A-4D: SEM surface images of CdSeTe (FIG. 4A) and CdSeTe coated with PVK (FIG. 4B), and SEM cross section images of CdSeTe (FIG. 4C) and CdSeTe coated with PVK (FIG. 4D).

FIGS. 5A-5F: JV parameters for CdSeTe/PVK/Au devices, along with CdSeTe/Au controls (FIGS. 5A-5D). FIG. 5E shows the JV curve for the best CdSeTe/PVK/Au device and the best CdSeTe/Au control. FIG. 5F shows the EQE for the best CdSeTe/PVK/Au device and the best CdSeTe/Au control.

FIG. 6: Table 1, displaying JV parameters of the median and best cells for various devices and lightsoak conditions from study #1 in the examples herein.

FIG. 7: V_{oc} for CdSeTe/PVK/Au devices with various pre-HTL-deposition thermal processing temperatures, along with CdSeTe/Au controls.

FIG. 8: Results of a 24-hour lightsoak V_{oc} for the full-factorial study #3 in the examples herein, with CdSeTe chemical surface etch, pre-HTL-deposition thermal process exposure, and HTM type skewed.

### DETAILED DESCRIPTION

Throughout this disclosure, various publications, patents, and published patent specifications are referenced by an identifying citation. The disclosures of these publications, patents, and published patent specifications are hereby incorporated by reference into the present disclosure in their entirety to more fully describe the state of the art to which this invention pertains.

Many materials and methods exist at the development stage for hole transport layers (HTLs) for CdTe-based PV devices. The current commercial back contacts for CdTe:As utilize ZnTe:N, while other manufacturers use ZnTe:Cu, which is less desirable due to diffusion and related issues. ZnTe:N is a standard contact in the photovoltaic industry that works with a CdTe:As absorber layer. Relatively few back contact materials are known for CdTe-based devices. However, it would be desirable for a different back contact structure to be developed, at least because the use of Te involves some modest cost.

Provided herein are polymeric materials which, when introduced at the back contact surface of the light absorber, allow for the fabrication of highly efficient cadmium telluride (CdTe) or cadmium selenium telluride (CdSeTe) PV solar cells. When compared to a laboratory reference cell which omits the back interface layer (BIL), the conversion efficiency under standard solar illumination may increase by approximately 3.7%.

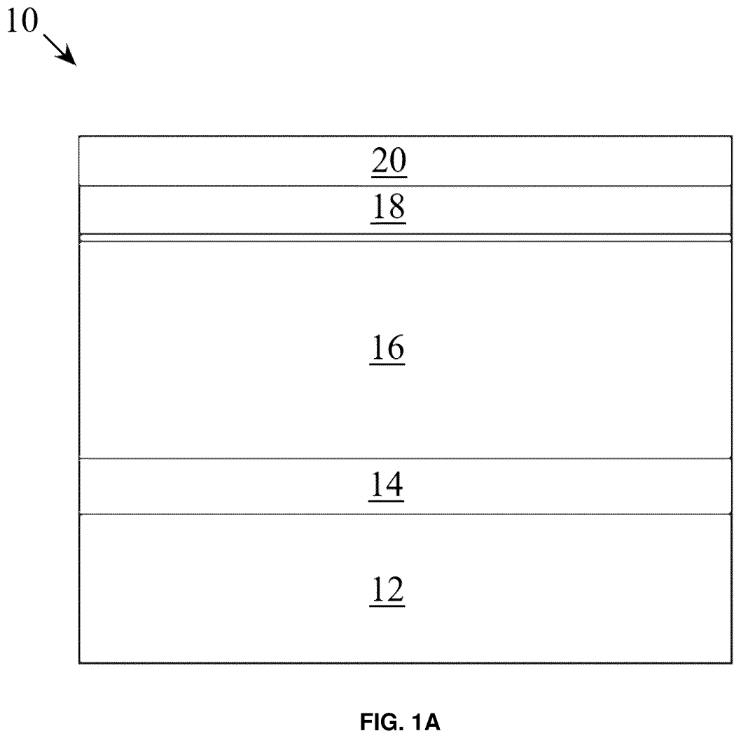

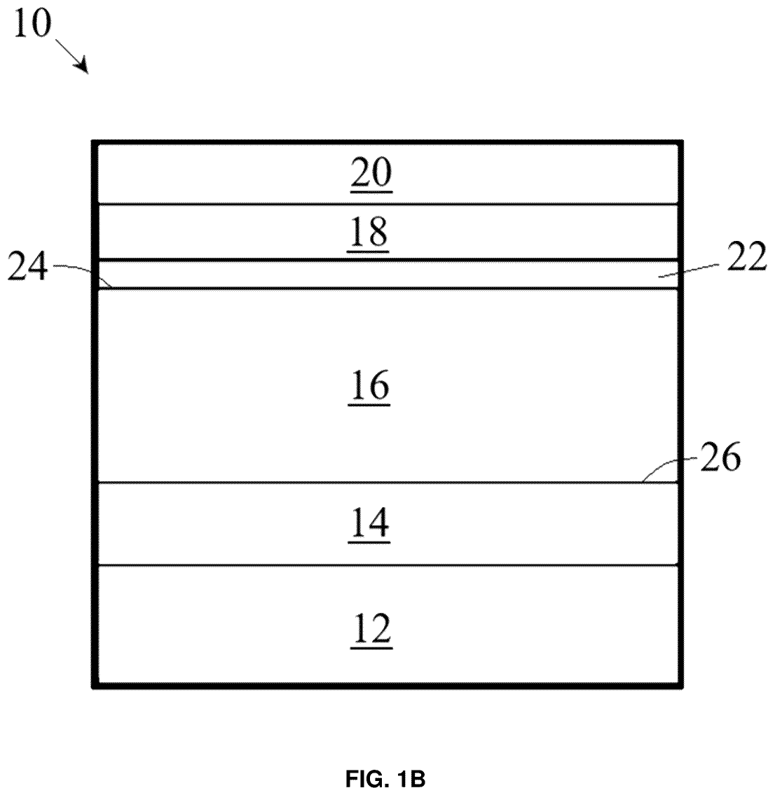

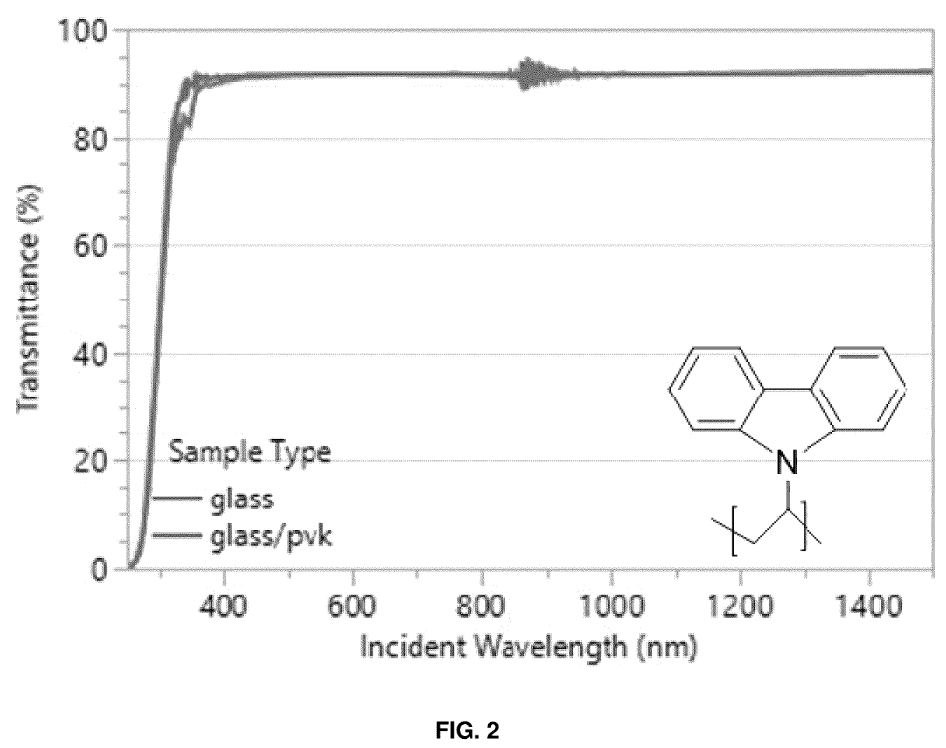

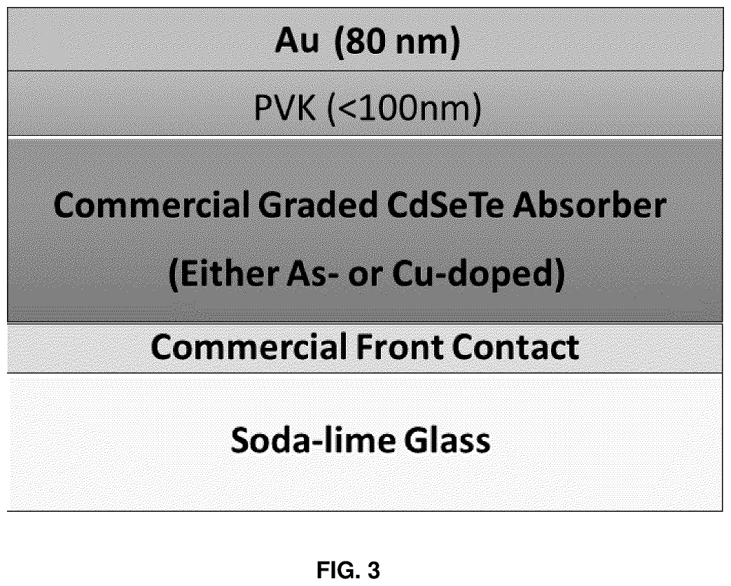

Referring now to FIG. 1A, a photovoltaic device 10 may include a layer stack having a support 12, a front contact 14, an absorber layer 16, a hole transport layer 18, and a back contact 20. Each of the layers 12, 14, 16, 18, 20 may be deposited through conventional thin film deposition techniques including, but not limited to, physical vapor deposition (PVD) methods such as sputtering or evaporation, chemical vapor deposition (CVD) methods such as low-pressure chemical vapor deposition (LPCVD), atmospheric pressure chemical vapor deposition (APCVD), or metalorganic chemical vapor deposition (MOCVD), atomic layer deposition (ALD), spray pyrolysis, spin coating, electroplating, sol-gel methods, screen printing, inkjet printing, or doctor blade coating.

The support 12 may be a substrate or superstrate, depending on the orientation in which the photovoltaic device 10 is manufactured. For example purposes, FIG. 1A illustrates a substrate orientation. When the support 12 is a substrate, the front contact 14 may be deposited on the support 12, followed by the absorber layer 16, the hole transport layer 18, and the back contact 20, along with any additional optional or intervening layers. When the support 12 is a superstrate, the back contact 20 may be deposited on the support 12, followed by the hole transport layer 18, the absorber layer 16, and the front contact 14, along with any additional option or intervening layers. Suitable materials for the support 12 include, but are not limited to, glass, soda-lime glass, and transparent plastics. The support 12 should be transparent so as to allow light through the support 12 to reach the absorber layer 16. The support 12 may also be flexible.

The front contact 14 acts as the negative-polarity electrode in the photovoltaic device 10. The front contact 14 may be a transparent conductive oxide (TCO) layer that is physically or chemically deposited onto the support 12. The front contact 14 may include a TCO material doped n-type with one or more dopants (such as fluorine, arsenic, phosphorus, antimony, bismuth, or nitrogen) such that the front contact 14 is an n-type layer, i.e., a layer having an excess of negative charge carriers. Non-limiting examples of suitable materials for the front contact 16 include tin oxide (SnO), doped SnO such as antimony-doped SnO, fluorine-doped SnO, or indium-doped SnO, indium tin oxide (ITO), fluorine-doped tin oxide (FTO), aluminum-doped zinc oxide (AZO), fluorine-doped indium oxide (IFO), antimony-doped tin oxide (ATO), zinc oxide (ZnO), aluminum-doped ZnO, gallium-doped ZnO, indium-doped ZnO, fluorine-doped SnO, or lithium-doped ZnO. The front contact 14 may be composed of multiple, differently doped layers, such as multiple TCO materials each doped n-type.

The absorber layer 16 may include cadmium and tellurium. The absorber layer 16 may, in some embodiments, further include selenium. In non-limiting examples, the absorber layer is CdTe. In other non-limiting examples, the absorber layer is CdSeₓTe₁₋ₓ. The absorber layer 16 may be formed from a CdSeTe material having a graded composition, i.e., where the amount of Se present varies along a thickness of the absorber layer 16. The absorber layer 16 may be doped p-type with suitable dopants including, but not limited to, copper, gold, silver, boron, indium, gallium, or combinations thereof. The p-type absorber layer 16 forms a photovoltaic heterojunction with the n-type front contact 14. In other embodiments, when intervening layers are present between the front contact 14 and the absorber layer 16, the absorber layer 16 forms the photovoltaic heterojunction with an intervening n-type layer. The absorber layer 16 may be formed from any of the thin film deposition methods described above, and may be deposited directly on the front contact 14 or an intervening n-type layer. Referring to FIG. 1B, the absorber layer 16 forms a photovoltaic heterojunction 26 at the interface between the absorber layer 16 and the adjacent n-type front contact 14 (when no intervening layers are present).

The absorber layer 16 may be a bulk material, and may be subjected to a conventional CdCl₂ treatment and annealing process. This process helps to improve the crystallinity, grain size, and electrical properties of the CdTe-based absorber material, ultimately enhancing device performance. The layer stack with the absorber layer 16 deposited is placed in a furnace or a similar setup, and a solution of CdCl₂ is applied onto the CdTe-based surface. The layer stack is then heated to a specific temperature, typically in the range of 350° C. to 450° C., in the presence of a controlled atmosphere, such as dry nitrogen or forming gas (a mixture of nitrogen and hydrogen). Afterward, the layer stack may be rinsed with deionized water to remove excess CdCl₂ residue from the absorber layer 18. The layer stack is then dried thoroughly to ensure the removal of any moisture before further processing. This annealing process involves CdCl₂ acting as a “fluxing” agent during the recrystallization process. This leaves the CdTe-based material heavily doped with Cl-containing species.

The hole transport layer 18 includes a polymeric material such as, but not limited to, poly(9-vinylcarbazole) (PVK). The hole transport layer 18 may also be doped with one or more p-type dopants such as, but not limited to, 4-tert-butylpyridine (4-TBP), lithium bis(trifluoromethanesulfonyl)imide (Li-TFSI), or cobalt(III) 2,2′,2″-(1,3,5-benzinetriyl)-tris(1-phenyl-1-H-benzimidazole) (FK209-Co).

PVK has the following structural formula:

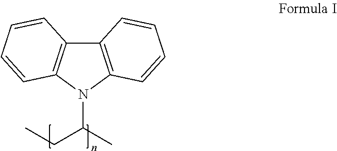

where n is an integer. Multiple PVK deposition methods are possible, including methods which involve lower temperatures than conventional back contact structure deposition methods. The lower temperature processing alleviates some materials issues in CdTe-based PV devices. Compared to other organic hole transport materials in particular, stress testing shows that PVK is robust to temperatures and light representative of field conditions. Advantageously, the PVK band structure is well aligned with the CdTe band structure. PVK is relatively easy to synthesize and thermally stable. PVK does not require copper present as a dopant. In fact, PVK works well in a copper-free device. Also, PVK is made of Earth-abundant elements, namely, carbon, hydrogen, and nitrogen.

The hole transport layer 18 facilitates the flow of electricity and acts to minimize electron-hole recombination by providing a region of the photovoltaic device 10 in which valence band positive charge carriers (holes) can easily diffuse while simultaneously repelling conduction band negative charge carriers (electrons). The hole transport layer 18 can be deposited through any of the thin film deposition techniques described above. In one non-limiting example, PVK is deposited upon the absorber layer 16 by a solution-based spincoating method to form the hole transport layer 18. However, prior to deposition of the PVK on the absorber layer 16, the absorber layer 16 may be chemically and thermally treated in such a way as to leave an exposed absorber surface in a cadmium- and oxygen-rich state (i.e., a mixture of CdO and CdTeO). Referring now to FIG. 1B, the photovoltaic device 10 may therefore include an optional Cd-rich oxidized interface layer 22 on the surface 24 of the absorber layer 16 opposite the photovoltaic heterojunction 26, between the absorber layer 16 and the hole transport layer 18.

Also, a bath sequence involving thermally annealing both before and after deposition of the hole transport layer 18 may be employed. The layer stack with the absorber layer 16 deposited can be exposed to a bath sequence involving KOH and deionized water, followed by a DI water rinse and air drying, or exposure to an acid/DI water solution for a period of time followed by a DI water rinse and air drying. After this bath sequence, the layer stack can be thermally annealed to a temperature of about 250° C. Then, the hole transport material 18 may be spin coated onto the absorber layer 16, and the subsequent layer stack can be thermally annealed at a temperature of about 130° C.

As described in the examples herein, it has been found that using PVK as the hole transport layer 18 results in improved power conversion efficiency (PCV) after a 24-hour light soak compared to comparable devices which do not include PVK as a hole transport layer 18. Specifically, as shown in the examples herein, a PVK-containing device yields a 0.5% absolute improvement and a 2.7% relative improvement in PCE compared to control devices. When compared to control devices which lack a hole extraction layer, the PVK-containing device resulted in higher photoconversion efficiency (3.7% relative benefit over controls). Without wishing to be bound by theory, it is believed that this photoconversion efficiency benefit is largely due to the preclusion of a Schottky diode that tends to form at the standard device's CdTe/Au interface, resulting in higher open-circuit voltage and less current loss from series resistance.

Advantageously, PVK is a relatively cheap organic hole transport layer and can be deposited through lower temperature methods compared to other hole transport materials. The use of lower temperature processes alleviates some materials issues in CdTe-based device fabrication, because some CdTe-based devices include materials, or utilize materials during manufacturing, which are heat-sensitive. PVK has been previously used in photodetectors and in nanocrystal-assembly PV devices. However, in accordance with the present disclosure, using PVK in a thin film, bulk CdTe-based PV device provides improved performance. Moreover, the PVK band structure is well aligned with the CdTe band structure, allowing PVK to serve as an ideal hole transport material in a CdTe-based device.

The selection of organic hole transport materials to be applied to CdSeTe PV devices is a choice which involves careful consideration of the optoelectronic properties of the hole transport materials. PVK can be used without, for instance, ZnTe, advantageously allowing for a back contact structure to be made without tellurium.

The back contact 20 is a highly conductive material which serves as the positive-polarity electrode (i.e., a collector of holes). The back contact 20 may be, for example, gold, molybdenum, copper, nickel, arsenic, indium-doped tin oxide (SnO:In), indium-doped cadmium oxide (CdO:In), titanium, silver, or alloys or combinations thereof. The back contact 20 may be a p-type layer. The back contact 20 may be a layer having a thickness ranging from about 50 nm to about 100 nm. However, in some non-limiting examples, the back contact 20 is not copper and does not include any copper. Copper, which when present can migrate within the photovoltaic device 10, may degrade PVK in the hole transport layer 18 over time. It has been observed that when the hole transport layer 18 is PVK and copper is present in the device 10, device performance may degrade with time. Therefore, in some embodiments, the entire photovoltaic device 10 is free of copper.

In use, light enters the photovoltaic device 10 through a sunny side 22 and may travel to the absorber layer 16 where the light is absorbed. Light of sufficient bandgap (meeting or exceeding the bandgap of the absorber layer 16) excites electrons from the valence band of the absorber layer 16 to the conduction band of the absorber layer 16. This process creates electron-hole pairs, where electrons are liberated from their atomic orbits, leaving behind positively charged holes in the valence band. Due to the internal electric field generated by dopants, the liberated electrons and holes are spatially separated. Electrons migrate towards the n-type (electron-rich) region while holes migrate towards the p-type (hole-rich) region of the photovoltaic device 10. As the electrons and holes migrate towards their respective regions, they create a flow of electrical current within the photovoltaic device 10. This flow of electrons constitutes an electric current in an external circuit connected to the photovoltaic device 10. The separated charge carriers (holes and electrons) are collected by the back contact 20 and the front contact 12, respectively, which act as electrodes present on the top and bottom surfaces of the photovoltaic device 10. These electrodes provide electrical contacts for the external circuit and facilitate the extraction of electrical energy generated by the photovoltaic device 10.

Although FIGS. 1A-1B depict a unifacial device 10, the present disclosure also encompasses bifacial and tandem solar cells and other photovoltaic devices. A polymeric hole transport material such as PVK is useful in any CdTe-based photovoltaic device. Photovoltaic devices with either CdTe or CdSeTe absorber layers and a PVK hole transport layer exhibit improved photoconversion efficiency compared to at least CdSeTe/Au control devices.

### Examples

Poly(9-vinylcarbazole) (PVK), an organic hole transport material (O-HTM), was used as the hole transport layer (HTL) for cadmium selenide telluride (CdSeTe) PV devices. The initial study showed that, in the case of arsenic-doped CdSeTe absorber devices, CdSeTe/PVK/Au devices demonstrated improved photoconversion efficiency (PCE) (best cells 19.8% vs. 19.2% control, condition medians 18.6% vs. 18.1%) after 24 hours at 1 Sun lightsoak, driven by improved open-circuit voltage (V_{oc}) (medians 854 mV vs. 836 mV), compared to CdSeTe/Au control devices. This represented an approximate 3% relative difference in PCE performance between PVK devices and controls. In a second study, a ˜2% relative PCE/V_{oc} benefit of PVK-HTL devices was demonstrated, but overall device performance was bound to sub-19% PCE throughout the sample set. Separately, intentional variation in the CdSeTe absorber back surface preparation immediately before PVK-HTL deposition indicated that the benefit of said O-HTM was confined to samples with the proper cadmium-rich CdSeTe surface state. A third study, this one being a full factorial study of interactions between relevant CdSeTe surface preparation states and O-HTM option, while reproducing the PVK-HTL device performance advantage to some degree, also indicated that some of the previously demonstrated ˜2-3% relative PCE/V_{oc} benefit was due to the CdSeTe surface preparation state. An additional O-HTM that has been underutilized in the CdSeTe-based PV field, poly(N,N′-bis-4-butylphenyl-N,N′-bisphenyl)benzidine (poly-TPD or PTPD), demonstrated large PCE benefits compared to no-O-HTM controls in this third study as well. In sum, a CdSeTe: As/PVK/metal back contact film structure is a useful structure, though the performance benefit offered by PVK-HTL may be most beneficial for a particular process space.

Organic hole transport materials (O-HTM or HTM) involve lower-energy wet chemistry deposition processes and boast a large degree of customizability by way of monomer functionalization using organic synthesis methods and the mixing of different monomer species into copolymers. Though thermal stability has been a concern regarding the usefulness of this class of materials in CdTe PV module incorporation before, O-HTMs with thermal stability that meets the requirements of CdTe PV HTLs have already been synthesized.

Several O-HTMs for which the highest occupied molecular orbital (HOMO) and lowest unoccupied molecular orbital (LUMO) meet the requirements for good HTL function in CdTe-based PV devices have been identified. One such O-HTM is poly(9-vinylcarbazole) (PVK). Several rounds of experiments have been undertaken to determine the effect of a PVK-HTL using a CdTe-based absorber material from First Solar, Inc. These examples report the device performance results of said studies.

### Methods and Procedures

### Materials

Gold pellets (Au) for thermal evaporation processes were procured from Kurt J. Lesker Company. Lithium-bis(trifluoromethanesulfonyl)imide (Li-TFSI) were procured from Ossila. Acetonitrile, 4-tert-butylpyridine (4-TBP) (98%), chlorobenzene (anhydrous, 99.8%), hydrogen peroxide (H₂O₂) (30 wt. %), poly(N,N′-bis-4-butylphenyl-N,N′-bisphenyl)benzidine (poly-TPD), and poly(9-vinylcarbazole) (PVK, average Mn 25-50 k) were all procured from Sigma-Aldrich. Hydrochloric acid (HCl) (12M, aqueous) was procured from Thermo Fisher Scientific. Potassium hydroxide (KOH) was procured from VWR Chemicals. Chemicals did not undergo additional purification or other processing before use in the procedures that follow.

The starting thin film stack used in these examples was composed of 100 cm² square soda-lime glass/front contact transparent conducting oxide (TCO)/cadmium selenide (CdSe)/CdTe coupons, where the CdTe absorber was doped with arsenic (As), provided by First Solar, Inc. These absorber stacks were deposited on the proprietary soda-lime glass/tin-oxide-(SnO) based substrates (NSG-make) using vapor transport deposition (VTD) in a CdSe/CdTe bilayer. After breaking vacuum, the CdSe/CdTe films underwent a cadmium chloride-(CdCl₂) assisted recrystallization process in which interdiffusion between the CdSe and CdTe takes place, resulting in a graded cadmium selenide telluride (CdSeTe) absorber. The exact composition of the proprietary front contact, the As-doping methodology, or the CdCl₂-assisted recrystallization process were unknown. Over the course of CdSeTe surface preparation and HTL deposition, these 100 cm² coupons were either cut down to 25 4 cm² square samples or 16˜1 inch² square samples.

### Hole Transport Material Solution Mixing

PVK/chlorobenzene and PTPD/chlorobenzene solutions (various molar concentrations on the order of 10 mM, collectively referred to as O-HTM solutions) were prepared by weighing the dry organic compound, adding the dry organic to a vial of chlorobenzene solvent, closing the vial, and sonicating the mixture for 1 hour at about 65° C. All O-HTM solutions were doped with small volumes of 4-TBP such that the moles 4-TBP/moles O-HTM fraction was ˜0.28. For PTPD solutions, small volumes of concentrated Li-TFSI/acetonitrile solution was added in such a way as to bring the moles Li-TFSI/moles HTM fraction to 0.1 (10% Li-doping).

### Device Fabrication

One of six possible CdSeTe surface preparation processes was utilized for each CdSeTe sample, which may have included a chemical processing step (chemical etch) and/or a pre-HTL-deposition thermal processing step. All CdSeTe surfaces were either spared exposure to a chemical etching process, exposed to a bath sequence that ended in a 1.3 M KOH/deionized water (DI water) solution for 1 minute followed by a DI water rinse and air dry, or exposed to an 800 μM HCl/DI water solution for 30 seconds followed by a DI water rinse and air dry. After CdSeTe samples had been exposed to their assigned chemical etch process, samples were either exposed to a box oven thermal process for 15 minutes where the temperature set point of the oven was usually 250° C. (some exceptions to this exact temperature are called out in the Results and Discussion section below) or were not thermally processed before the HTL deposition step.

At this processing stage, CdSeTe samples either had no O-HTM deposited on them or had one of the two O-HTM solutions described above deposited using spincoating (30 seconds at 6000 rpm). After deposition, samples with PVK-HTL or PTPD-HTL were thermally processed at 130° C. for 15 minutes on a hot plate in open air. Samples that did not undergo O-HTL deposition were also not exposed to thermal processing at this stage.

For the first two studies discussed in the Results and Discussion section, the surface preparation that “control” samples were exposed to always involved the HCl bath chemical etch followed by the 250° C./15-minute box oven thermal processing, while CdSeTe absorber samples upon which PVK-HTLs were deposited always received KOH chemical etch sequence and were usually exposed to the pre-HTL-deposition 250° C. thermal process.

Following CdSeTe surface treatments and possible HTL deposition/thermal treatment, samples were placed in a vacuum chamber where 80 nm of Au was deposited onto the film side by thermal evaporation. After Au deposition, cell definition processing was performed using a 532 nm scribing laser with film-side incidence to cut the Au, HTL, and CdSeTe layers into ˜9 mm² square cells (with intention of leaving the front contact TCO intact). An indium contact was soldered onto a patch of exposed front contact TCO on the four edges of each rectangular sample, with any cell never more than 12 mm away from this indium front contact in order to minimize resistive loss differences between cells due to variable charge carrier path lengths through the transparent front contact.

### Current Density-Voltage Characterization and Lightsoak Exposure

Current density-voltage (JV) characteristic curves of the devices described above were measured under simulated AM1.5G illumination (exposure duration ˜3 s) at room temperature using a Keithley 2440 digital source meter unit and a LED solar simulator (MiniSol model LSH-7320) received from Newport. For lightsoak, the glass side of the samples were exposed to ˜100 mW/cm² incident power illumination from a mercury (Hg) vapor lamp (MVR1000) while the samples rested on a hotplate set to 70° C. A previous study on the temperature of CdSeTe/Au devices under this lightsoak condition found the temperature of the samples' film side to stabilize around 90° C., but in-situ temperature was not monitored during these studies. After prescribed lightsoak exposure intervals, samples were removed from the Hg vapor lamp/hotplate apparatus, allowed to cool for 1-20 minutes, and their JV characteristics were measured again before the samples were either stored in a dark cabinet or returned to the lightsoak apparatus. No effort was made in these examples to probe separately the effects of light-exposure and heat-exposure on CdSeTe-based PV device JV performance. Device exposure to elevated temperatures under low illumination and exposure to bright light under constant temperature may or may not affect JV characteristics for CdSeTe-based PV devices differently, but the effects of both lightsoak and temperature soak are convoluted in these examples.

### Additional Characterization Apparatus

Optical transmittance and reflectance spectra of HTM films deposited on borosilicate microscope slides were measured using a Perkin-Elmer Lambda 1050™ spectrophotometer. External quantum efficiency (EQE) was measured using a PV Measurements Inc. instrument. Scanning electron microscopy (SEM) images were obtained by use of a Hitachi S-4800 scanning electron microscope.

### Initial HTM Deposition Experiment Design

Initial HTM deposition process customization for the all three O-HTMs was performed in separate experiments designed using the Design of Experiments (DOE) platform in JMP-Pro 17 statistical analysis software (SAS Institute Inc.). The process parameters that were varied include 1) CdSeTe surface chemical etch (acid bath sequence vs. base bath sequence), 2) pre-HTM-deposition thermal treatment (250° C./15-minutes exposure or unexposed), 3) target HTL thickness (modulated through HTM solution concentration and spincoater spin speed), and 4) post-HTM-deposition heat treatment. JV data from these initial experiments were modeled using a linear regression (similar to that described below) and a “champion” condition for target HTL thickness for each O-HTM type.

### Results and Discussion

### Study #1: Initial Deposition Process Optimization Experiments and Champion Device Run

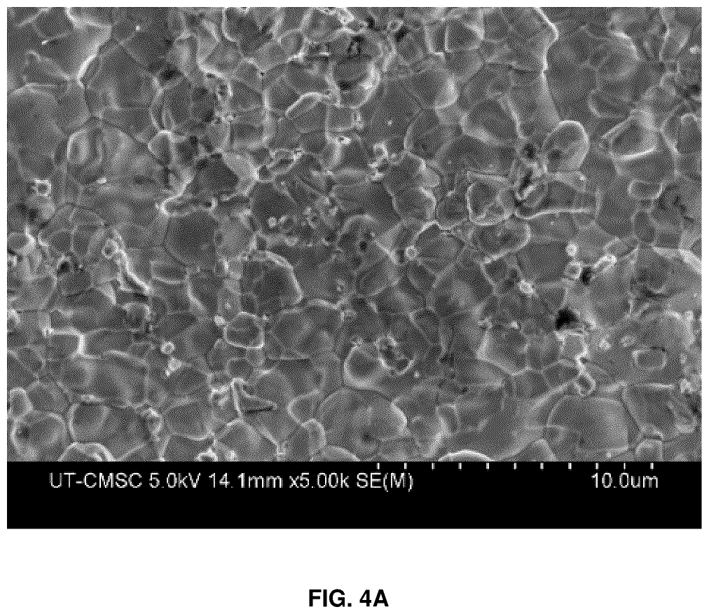

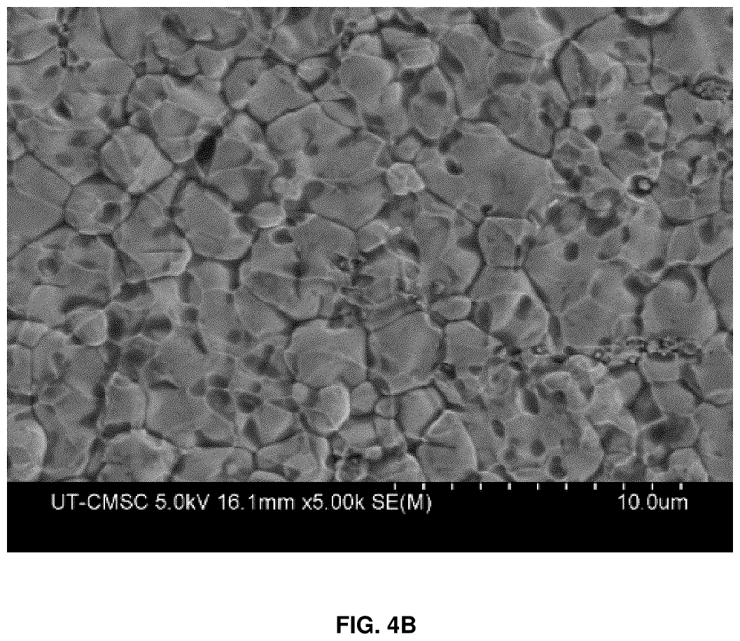

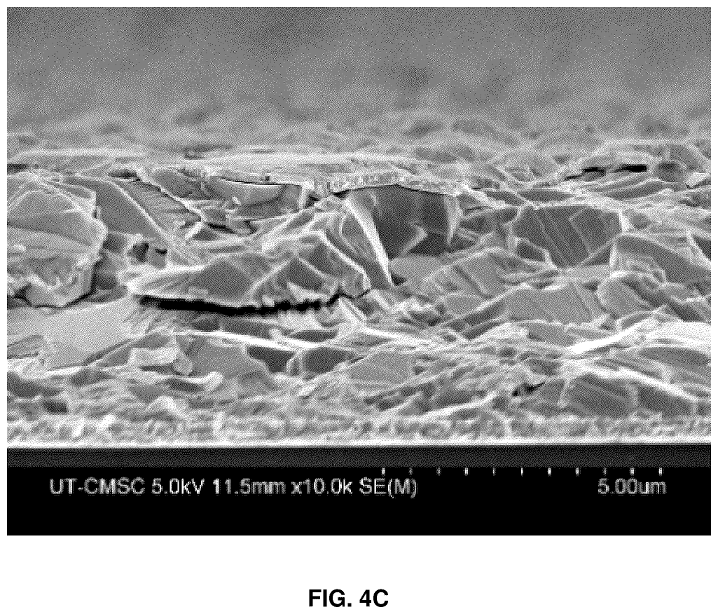

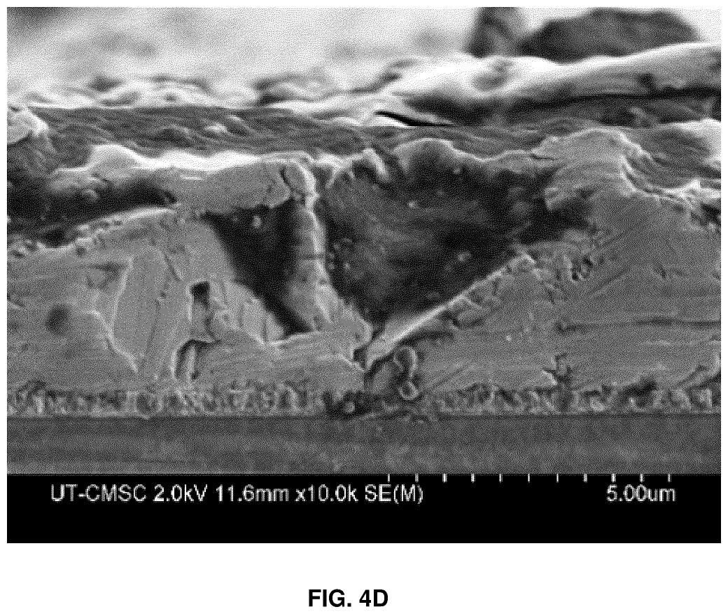

The CdSeTe surface preparation process which yielded the best JV performance for PVK-HTL devices in the first study involved exposure to the KOH bath sequence followed by a 250° C., 15-minute box oven thermal process. Without wishing to be bound by theory, it is believed that this left the CdSeTe surface in a Cd-rich state and also highly oxidized. From SEM surface images and cross-section images (FIGS. 4A-4D), the PVK film appears patchy and discontinuous on the CdSeTe surface; this makes determination of a “film thickness” difficult with in-house equipment. The thin, partial coverage of the PVK may be important to compensate for this O-HTM's relatively low hole mobility of 2.5×10⁻⁶ cm²/V*s. Samples were heat treated on a hotplate after PVK deposition at 130° C. for 15 minutes in air.

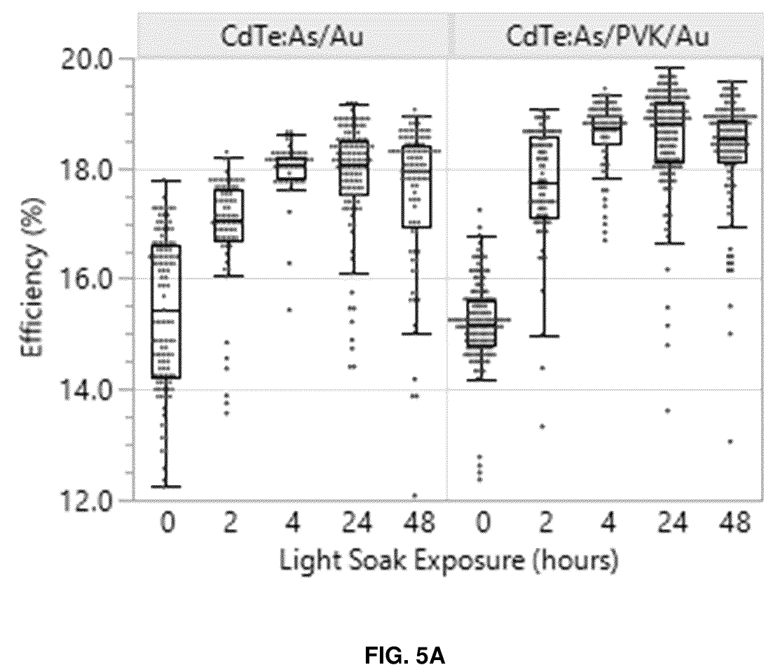

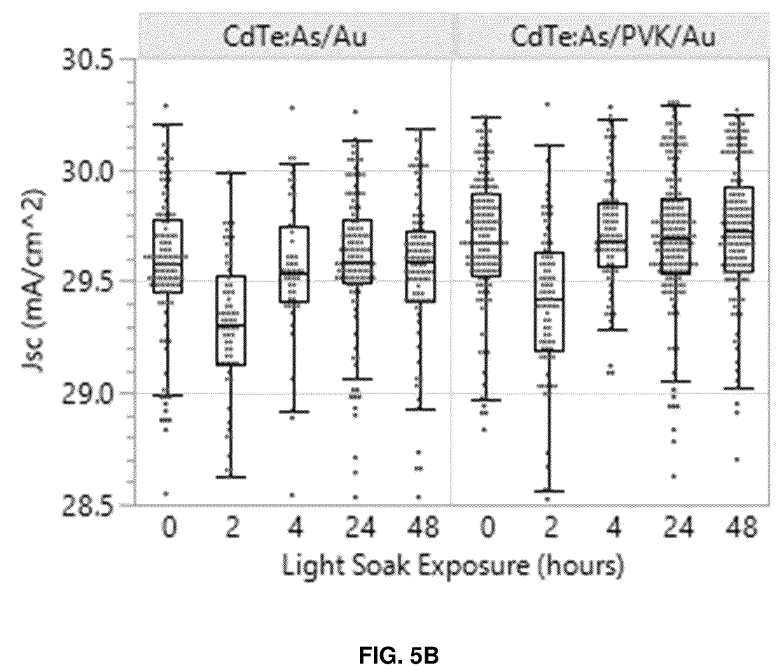

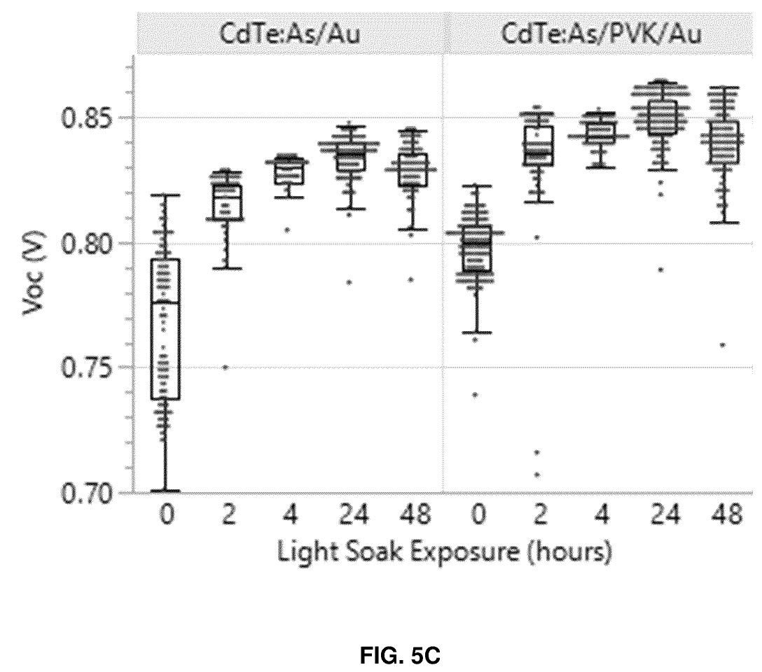

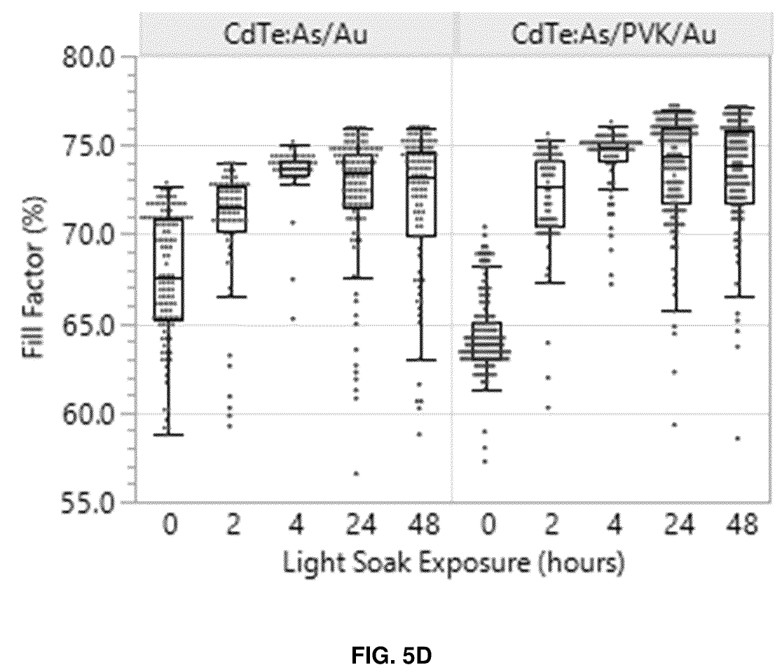

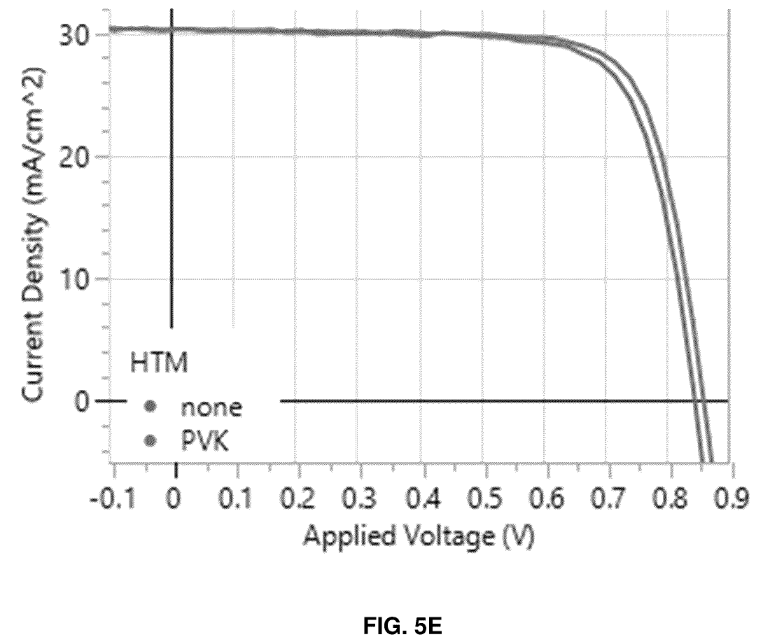

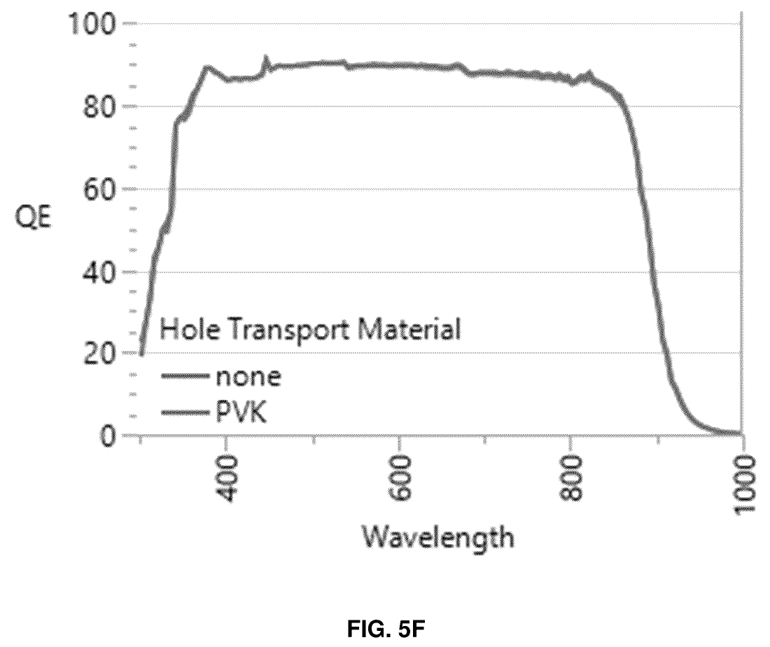

In the case of CdSeTe absorbers, PVK-HTL devices demonstrated “darksoaked” PCE (measured immediately following device fabrication, without elevated light or temperature exposure) comparable to CdSeTe/Au controls (median PCE 15.1% vs. 15.4% controls, see FIG. 5A). However, CdSeTe/PVK/Au devices underwent an even more pronounced JV enhancement than controls when exposed to 1 day of 1 Sun lightsoak. Median V_{oc} jumped to 854 mV (2.1% relative advantage over controls) and median FF jumped to 73.4% (roughly equal to controls). This resulted in a median post-lightsoak PCE of 18.6% for CdSeTe/PVK/Au devices, with a best cell reaching 19.8% PCE and a 2.7% relative median PCE advantage over controls. This PCE/V_{oc} advantage is largely maintained after a total 48-hours lightsoak.

When considering only the 24 hour lightsoaked JV data, the mean PCE difference between CdSeTe/PVK/Au devices and CdSeTe/Au control devices is 0.70% with t-test p-value of less than 1*10⁻⁴ with a 95% confidence interval. This p-value indicates a highly significant difference in population means in PCE between controls and PVK-HTL-incorporating devices after 24 hours lightsoak.

EQE curves, which were taken after 2 days of lightsoak, show that CdSeTe/PVK/Au devices have very similar spectral responses to CdSeTe/Au controls (J_{scQE} of 29.2 mA/cm² vs 29.4 mA/cm²) (FIG. 5E). This indicates that the PVK-HTLs did not affect charge extraction in this study.

In this same study, PVK was also screened as an HTL for Cu-doped CdSeTe devices. The results from that part of the study showed that CdSeTe: Cu/PVK/Au devices demonstrated a significant decay in device performance as the devices were exposed to additional intervals of lightsoak. As lightsoak is designed to simulate field-like conditions, this indicates PVK is a better HTL in Au-doped CdSeTe devices than Cu-doped CdSeTe devices.

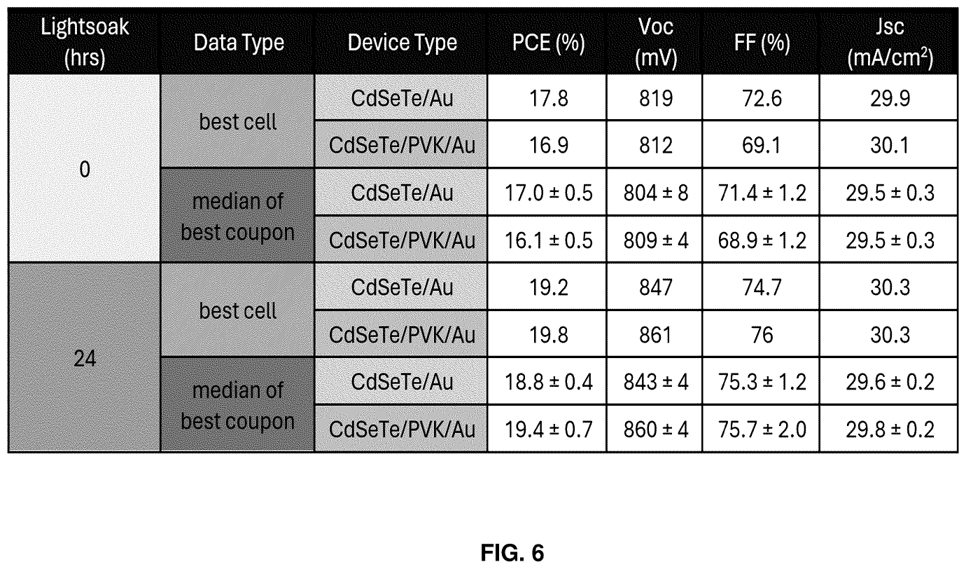

FIG. 6 shows Table 1, which displays the JV parameters of median and best cells for various devices and lightsoak conditions from study #1.

### Study #2: CdSeTe Cd-Rich Surface Preparation Skew

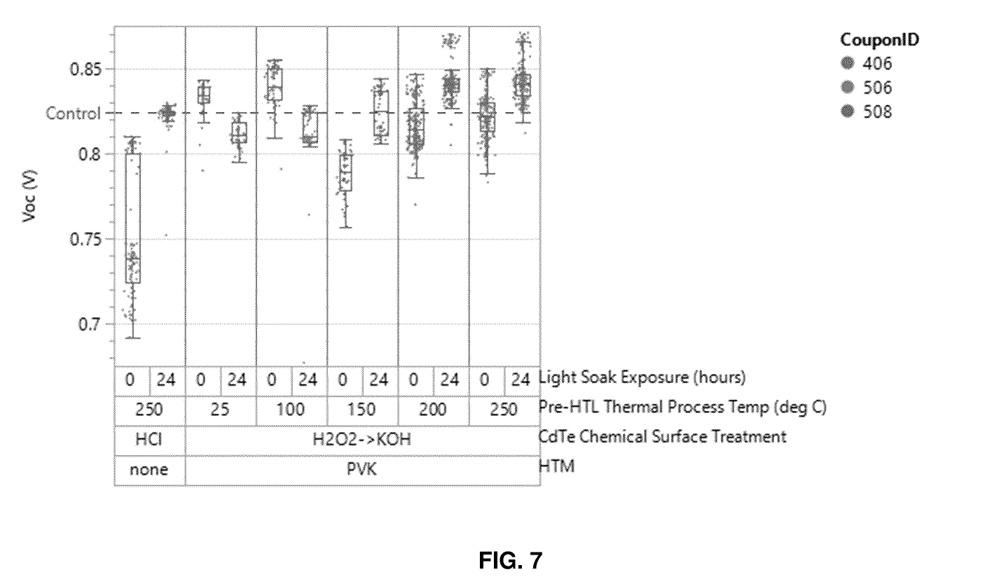

The comparison performed in study #1 was largely repeated in study #2, but with one thermal processing parameter skewed. CdSeTe/Au control devices again had the absorber surface exposed to the HCl bath/250° C. thermal process sequence, whereas CdSeTe/PVK/Au devices had absorber surfaces exposed to the KOH bath sequence. The parameter for PVK-HTL devices which was varied was the temperature of the thermal process that took place between chemical etch and HTL deposition, being varied from 50° C. to 250° C. with some representatives which were not exposed to an elevated-temperature process at all (labeled with “25° C.” in the thermal process parameter in FIG. 7). As shown in FIG. 7, there is 1) a clear dependence of post-lightsoak (24-hour) V_{oc} in PVK samples on the thermal processing temperature skewed, with the best performance obtained with 250° C. processing (medians 811 mV for no-thermal process devices vs. 841 mV for samples processed at 250° C.), and 2) a ˜2% relative V_{oc} difference between the best PVK device condition and controls (medians 824 mV controls vs. 841 mV PVK devices), which is a similar relative advantage the PVK devices demonstrated over controls in study #1.

### Study #3: Full-Factorial CdSeTe Thickness/Surface Preparation/O-HTM Interactions Skew

Study #2 raised the possibility that part of the passivating effect of the PVK-HTL structure was not due to the presence of PVK but was instead due to CdSeTe absorber surface preparation differences between the PVK-HTL devices (where CdSeTe absorbers were etched with KOH solution, likely leaving the surface in a Cd-rich state) and no-PVK devices (where CdSeTe absorbers were etched with HCl solution, likely leaving the surface in a Te-rich state). In order to definitively measure what device process knobs were responsible for what portions of the passivation effect seen in CdSeTe/PVK/Au devices, study #3 was a full-factorial skew of the CdSeTe surface etch, pre-HTL-deposition thermal process toggle, and PVK toggle. HTL deposition methods for PTPD (known as poly-TPD) were also being actively developed, so this was added as a parameter setting for HTM type (none, PVK, or PTPD).

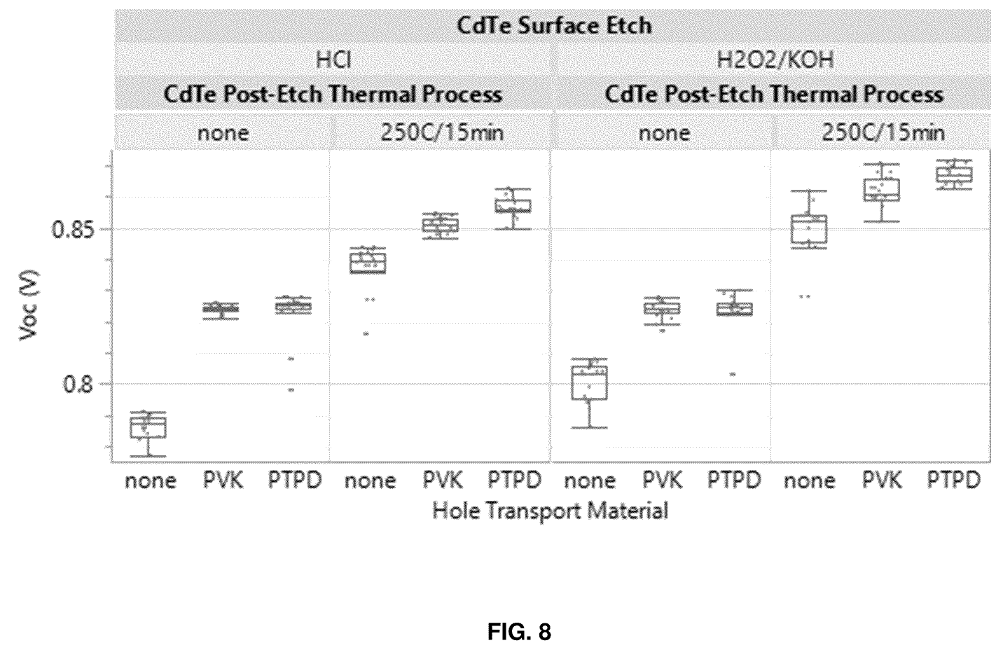

The results of study #3 (FIG. 8) do indicate that only about half of the V_{oc} benefit seen in study #2, about ˜1% relative difference in V_{oc} between PVK devices and controls, is due to the presence of PVK itself. In the case of devices in which CdSeTe surfaces receive a basic etch followed by a thermal process before HTL deposition, the relative V_{oc} advantage of PVK-HTL devices is 1% (median 853 mV control vs. 861 mV PVK-device), while in the case of CdSeTe surface receiving an acid etch followed by a thermal process before HTL deposition, PVK enjoyed a 1.4% relative advantage over controls (median 840 mV vs. 851 mV).

PTPD devices enjoyed a larger V_{oc} benefit over no-HTL devices in both surface etch cases; in the basic etch case, PTPD-HTL devices demonstrate a median 867 mV V_{oc}, while in the acid etch case, PTPD-HTL devices still demonstrate 856 mV V_{oc}. This was a larger V_{oc} benefit than both no-HTL devices and PVK-HTL devices in both CdSeTe surface state conditions.

### CONCLUSION

Three consecutive studies have demonstrated that PVK, when incorporated into CdSeTe-based PV devices as an HTL, confers at least a 1% relative V_{oc} advantage and substantial overall device performance advantage over CdSeTe control devices that do not incorporate an HTL. This performance benefit is robust to the state of the CdSeTe surface that PVK is deposited upon. However, in the studies in which CdSeTe/PVK/Au devices demonstrate some device performance benefit, the CdSeTe absorber layer was doped with arsenic and not copper; performance was unstable in CdSeTe:Cu/PVK/Au devices under field-like conditions.

Certain embodiments of the devices and methods disclosed herein are defined in the above examples. It should be understood that these examples, while indicating particular embodiments of the invention, are given by way of illustration only. From the above discussion and these examples, one skilled in the art can ascertain the essential characteristics of this disclosure, and without departing from the spirit and scope thereof, can make various changes and modifications to adapt the devices and methods described herein to various usages and conditions. Various changes may be made and equivalents may be substituted for elements thereof without departing from the essential scope of the disclosure. In addition, many modifications may be made to adapt a particular situation or material to the teachings of the disclosure without departing from the essential scope thereof.

What is claimed is:

1. A photovoltaic device comprising:
a front contact;
one or more layers on the front contact including a photovoltaic heterojunction, the photovoltaic heterojunction comprising an absorber layer, wherein the absorber layer comprises cadmium and tellurium;
a hole transport layer on the absorber layer, wherein the hole transport layer comprises poly(9-vinylcarbazole) (PVK); and
a back contact on the hole transport layer.

2. The photovoltaic device of claim 1, wherein the absorber layer comprises at least one of CdTe or CdSeTe.

3. The photovoltaic device of claim 1, wherein the back contact comprises Au.

4. The photovoltaic device of claim 1, wherein a dopant condition of the absorber layer is configured as either the absorber layer doped with arsenic, or the absorber layer not doped with copper, or the absorber layer doped with arsenic and not copper.

5. The photovoltaic device of claim 4, wherein the absorber layer comprises CdSeTe.

6. The photovoltaic device of claim 1, wherein the absorber layer is in direct contact with the front contact, and the photovoltaic heterojunction is formed between the front contact and the absorber layer.

7. The photovoltaic device of claim 1, wherein the PVK is doped with 4-tert-butylpyridine (4-TBP), lithium bis(trifluoromethanesulfonyl)imide (Li-TFSI), or cobalt(III) 2,2′,2″-(1,3,5-benzinetriyl)-tris(1-phenyl-1-H-benzimidazole) (FK209-Co).

8. The photovoltaic device of claim 1, further comprising a Cd-rich oxidized interface layer between the absorber layer and the hole transport layer.

9. The photovoltaic device of claim 8, wherein the Cd-rich oxidized interface layer comprises a mixture of CdO and CdTeO.

10. The photovoltaic device of claim 1, wherein the photovoltaic device is entirely free of copper.

11. The photovoltaic device of claim 1, wherein the one or more layers on the front contact is a plurality of thin film layers and the photovoltaic heterojunction is formed between a first contact layer having n-type conductivity and a second contact layer having p-type conductivity, the absorber layer forms the photovoltaic heterojunction with one or more other layers of the plurality of thin film layers.

12. The photovoltaic device of claim 11, wherein a dopant condition of the absorber layer is configured as either the absorber layer doped with arsenic, or the absorber layer not doped with copper, or the absorber layer doped with arsenic and not copper.

13. The photovoltaic device of claim 12, wherein the absorber layer comprises CdSeTe.

14. The photovoltaic device of claim 11, wherein the photovoltaic device is entirely free of copper.

15. A photovoltaic device comprising:
a first electrically conductive layer having n-type conductivity;
an absorber layer comprising cadmium and tellurium on the first electrically conductive layer, the absorber layer forming a photovoltaic heterojunction with either the first electrically conductive layer or an additional layer between the first electrically conductive layer and the absorber layer; and
a back contact structure on the absorber layer comprising a hole transport material and a second electrically conductive layer, wherein the hole transport material comprises poly(9-vinylcarbazole) (PVK) and the second electrically conductive layer has p-type conductivity.

16. The photovoltaic device of claim 15, further comprising a support and a transparent conductive oxide layer on the support, wherein the absorber layer comprises CdSeTe directly on the transparent conductive oxide layer, and the hole transport layer is between the absorber layer and the back contact layer.

17. The photovoltaic device of claim 16, further comprising a Cd-rich oxidized interface layer directly on the absorber layer and between the absorber layer and the hole transport layer.

18. A method of making a photovoltaic device, the method comprising:
exposing a layer stack having an absorber layer material comprising cadmium and tellurium deposited on a surface thereof to a bath comprising KOH;
thermally annealing the layer stack at a first elevated temperature for a first period of time;
depositing poly(9-vinylcarbazole) (PVK) from a solution onto the surface; and
thermally annealing the layer stack at a second elevated temperature for a second period of time, wherein the second elevated temperature is 150° C. or less.

19. The method of claim 18, further comprising doping the PVK layer with 4-TBP, Li-TFSI, and/or FK209-Co.

20. The method of claim 18, further comprising depositing a back contact on the PVK.
